(19) United States
(12) Patent Application Publication
(10) Pub. No.: US 2013/0069789 A1
(43) Pub. Date: Mar. 21, 2013

(54) Method And A Device For Recognizing Mechanical Impacts Upon Electrical Installations

(71) Applicant: Bender GmbH & Co. KG, Gruenberg (DE)

(72) Inventor: Dirk Pieler, Gruenberg (DE)

(73) Assignee: Bender GmbH & Co. KG, Gruenberg (DE)

(21) Appl. No.: 13/622,505

(22) Filed: Sep. 19, 2012

(30) Foreign Application Priority Data
Sep. 19, 2011 (DE) 102011082940.7

(51) Int. Cl. G08B 21/00; G01R 31/02

(52) U.S. Cl. 340/665; 324/511

(57) ABSTRACT

A method and a device recognizes mechanical impacts upon electrical installations. The device includes a functional electrical connection with a power supply network or a storage medium. At least one signal is recorded on the functional electrical connection in order to recognize the mechanical impact. Advantageously, the device can be incorporated into a photovoltaic installation with at least one solar current module.

### CROSS REFERENCE TO RELATED APPLICATION

The present application claims the benefit of German Patent Application No. 10 2011 082 940.7 filed Sep. 19, 2011, which is fully incorporated herein by reference.

### STATEMENT REGARDING FEDERALLY SPONSORED RESEARCH OR DEVELOPMENT

Not applicable.

### FIELD OF THE INVENTION

The invention relates to a method and a device for recognising mechanical impacts upon electrical installations comprising a functional electrical connection with a power supply network or a storage medium.

Furthermore the invention relates to a photovoltaic installation with at least one solar current module and with a device according to the invention.

### BACKGROUND OF THE INVENTION

Installations with electrical equipment for the production, transmission, conversion, distribution and application of electric energy are often erected in open spaces. As such solar current modules of photovoltaic installations, for example, must, of necessity, be installed on roofs or on open ground. Also stationary electrical equipment which is connected with electrical installations but is movable, such as machines or mobile generators, is often found in open spaces. These installation components are therefore exposed to mechanical impacts caused for example by a falling tree during a storm or by a collision with a construction vehicle on building sites. Since these electrical installations are often of considerable value they are also exposed to the risk of theft.

The risk of damage to, or theft of, such installation components always entails restrictions as regards availability, reliability of supply and cost effectiveness of the electrical installation. The installation operator will therefore endeavour to protect the electrical installation as comprehensively as possible against disadvantageous mechanical impacts.

Although unauthorised spatial accessibility can be made difficult by means of barriers and security systems, comprehensive protection against theft is possible only at considerably expense.

Security measures are known for photovoltaic installations for example, which, in addition to making accessibility difficult through conventional alarm systems such as motion sensors and video surveillance, make the solar current modules mechanically secure and in this way at least make dismantling difficult.

Known security measures, however, often require considerable interference with the technical design of the installation and either involve big investments or provide only insufficient protection against theft.

### SUMMARY OF THE INVENTION

The present invention therefore is based on the requirement to develop a method and a device for recognising mechanical impacts upon electrical installations which can be integrated into existing installations at little expense and permit permanent monitoring.

With regard to a method this objective is met in electrical installations including a functional electrical connection with a power supply network or a storage medium by recording at least one signal on the functional electrical connection to recognize a mechanical impact.

The invention is based on the idea of utilising an existing functional electrical connection of the installation to be monitored in conjunction with a power supply network or a storage medium such as a battery or a fuel cell. This functional electrical connection, in the simplest case, is an existing power supply line which is connected via an electrical equipment with the power supply network or a separate power supply; as an example this could be the feed line of an electric motor, a mobile generator or a solar current module. It is this functional electrical connection on which a signal, i.e. the temporal progression of a physical quantity such as the electrical voltage or amperage is recorded and utilised for recognising a mechanical impact. In the simplest case the recorded signal progression is based on the operating voltage or the operating current of the supply network. It could, however, also be an additionally imprinted variable such as a measuring current used for constant insulation monitoring in an IT network.

Without any constructional changes to the installation itself the existing signal is used to recognize a mechanical impact upon an already existing electrical line.

In a preferred design recognition of the mechanical impact is effected by comparing an actual value of the recorded signal or an actual value of variables derived therefrom with a required value.

A mechanical impact upon the installation component to be monitored is recognized in that the momentarily recorded signal, being the actual value, is compared with a preset or stored required value. Assuming that a mechanical impact leads to a change in the actual state of the recorded signal, a deviation of the actual value from the required value may indicate just such a mechanical impact. In particular, when recording additionally imprinted signals the recorded temporal progression of the actual value can be compared with stored (required value) progression patterns, in order to be able to recognize possible unusual events. In an intermediate step the recorded signal may be transformed into a derived variable, for example a recorded measuring current or a recorded measuring voltage for a known measuring setup may be initially converted into a resistance value which is then subjected to a comparison. An example of such an application would be the evaluation of the insulation resistance of an electrical installation.

Advantageously a sharp change in the actual value is utilised as a recognition criterion for a mechanical impact. By evaluating the temporal progression of the recorded actual value a sharp change in the actual value may be able to deliver an indication pointing to a disconnection of the electrical connection and thus to possible damage or disassembly.

In a further advantageous design a rate of change in the actual value is utilised as a recognition criterion for a mechanical impact. In this design the rate of change in the actual value is taken into consideration in a further step following recording the temporal progression of the signal. In particular in conjunction with recording additionally imprinted measuring signals which are subject to natural fluctuations, this evaluation is of importance.

Conveniently, recognition of a mechanical impact leads to an alarm signal being generated. The alarm may be triggered as a function of the construction and position of the electrical installation to be monitored in a conventional manner by means of an optical and/or acoustic alarm signal.

Advantageously the alarm signal may be transmitted remotely. This electronic signal may be transmitted wirelessly via a radio link or via a wired line to several reception points.

Advantageously permanent self-monitoring of the method for recognising mechanical impacts is performed. This offers a means of preventing the monitoring method itself from being deactivated due to unauthorised interference or tampered with.

Conveniently a ground connection of a device designed for executing the method is monitored. If, for example, in conjunction with insulation monitoring the signal recorded is the measuring current of an insulation monitoring device, monitoring can be extended to cover ordinary connections, in particular the ground connection and the self-supply of this device, in order to make tampering with the monitoring device itself difficult. In particular this can prevent the device from being disconnected or crippled and thus suppressing the triggering of an alarm.

With further advantageous designs of the method this may be operated in a cyclic manner or be activated only temporarily. Using one of these operating modes it is possible, in particular in the case of photovoltaic installations with insulation monitoring, i.e. where a measuring current is recorded, to achieve considerable savings in the required supply energy.

With regard to a device, the objective is met by a recording unit coupled to the functional electrical connection which records at least one signal on the functional electrical connection.

According to the invention the device for recognising mechanical impacts upon electrical installations comprises a recording unit which is coupled to the already existing electrical connection of the electrical installation or the electrical equipment, which means that it access signals already present on the electrical connection line.

In this way recognition of mechanical impacts is made possible at only little technical expense and without a major interference with the electrical installation whilst making use of an existing electrical connection.

An advantageous design is realised by a detection unit which, by comparing an actual value of the recorded signal with an actual value of variables derived therefrom, recognizes a mechanical impact and generates an alarm signal.

Such a detection device permits, by means of a comparison of the recorded actual values with pre-set or stored required values, an indication on a possible mechanical impact, since such an impact is usually accompanied by a sharp change in the recorded signal. Further, the detection device is equipped with means for generating an alarm signal.

Preferably the device comprises a transmission unit for remote transmission of an alarm signal. The transmission unit may include components for radio transmission and/or wired transmission in order to be able to receive the alarm signal in a decentralised manner at different locations. For example, the alarm signal could be sent to a central monitoring station (CMS) via a digital data interface in the form of an encoded data packet via radio or cable. This may be located, for example, at the installation operator, a security service company or the fire service. These would be places which carry out evaluation and further processing of the data-encoded telegram-type electronic alarm message.

Advantageously the device includes a unit for permanent self-monitoring in order to prevent it from being tampered with, in particular prevent the alarm function from being rendered inoperative.

In a preferred design the recording unit for recording signals for determining the actual value is an insulation resistance.

Insulation monitoring as a protection technique plays an important role in particular in ungrounded IT systems which occur, for example, in photovoltaic installations. An insulation-resistance measuring device constantly monitors the insulation resistance of an electrical connection and triggers an alarm in case the insulation resistance drops below a preset response value. Because the recording unit determines the insulation resistance as an actual value (derived from a signal), a mechanical impact can be recognized on the basis of this temporal progression of the insulation resistance in the detection unit. The device according to the invention therefore can be designed as an insulation-monitoring device and in addition be used for recognising mechanical impacts.

Typically the insulation resistance changes over time, for example with photovoltaic installations as a function of the environmental conditions such as light intensity or air humidity, but these changes characteristic for a certain installation can be distinguished from sharp changes caused by a unique mechanical impact. A progression characteristic for a certain installation can have been previous “learnt” and can be used as a temporal reference pattern for the comparison with the recorded actual value. Unusual deviations which exceed or drop below previously fixed limit values are then used as an indication for a mechanical impact and can trigger an alarm signal.

In a further design the recording unit is designed for recording signals for recognising an electric arc.

In this design the device according to the invention makes use of the existing operating voltage of the electrical installation for recognising a mechanical impact. If the installation is live and if a current flows through the supply line, arcing occurs as from an amperage limit value when the installation or the electrical equipment is disconnected from the supply circuit. This effect can be utilised in order to detect disconnection of the installation component to be monitored. An electric arc sensor associated with the recording unit, which can be arranged at a random location, ideally at locations inaccessible to unauthorised persons, unequivocally identifies the electric arc and triggers an alarm signal.

Advantageously a photovoltaic installation with at least one solar current module comprises a device according to the invention. The invention is equally suitable for day and night monitoring of a photovoltaic installation. Since these installations, for reasons of availability and security of supply are usually implemented as an IT system with insulation monitoring, the present invention, in the design as an insulation monitoring device, offers the possibility of a cost-effective, complete theft-proof monitoring of valuable solar current modules.

On the basis of ascertaining and evaluating the temporal progression of the insulation resistance unusual events can be recognized and reported. The invention permits an immediate generation of an alarm signal irrespective of which part of the photovoltaic installation is interfered with. Further components of the photovoltaic installation connected or integrated with the solar current modules can be included in the monitoring, such as DC/DC or DC/AC converters.

### BRIEF DESCRIPTION OF THE DRAWINGS

Further advantageous design features are mentioned in the following description and the drawings which discuss a preferred embodiment of the invention by way of an example. In the drawings:

FIG. 1 shows a functional block diagram of a device according to the invention for recognising mechanical impacts upon electrical installations; and

FIG. 2 shows a block diagram of a photovoltaic installation with a device according to the invention.

### DETAILED DESCRIPTION OF THE EXAMPLE EMBODIMENTS

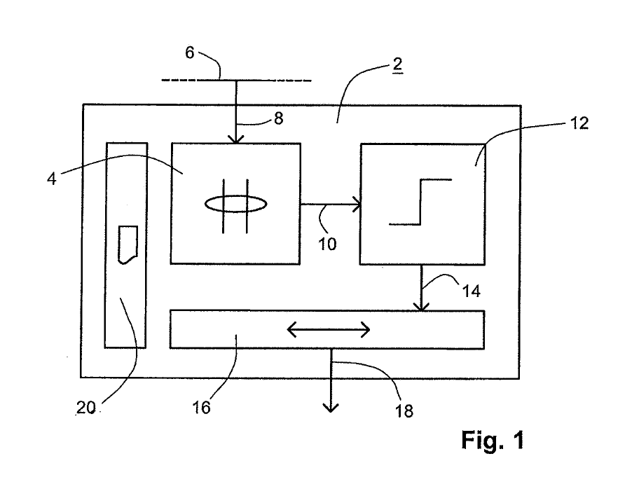

FIG. 1, in a functional block diagram, shows the construction of a device 2 according to the invention. Shown are the essential components for implementing a method according to the invention for recognising mechanical impacts upon electrical installations. As such this diagram serves to illustrate the corresponding procedure.

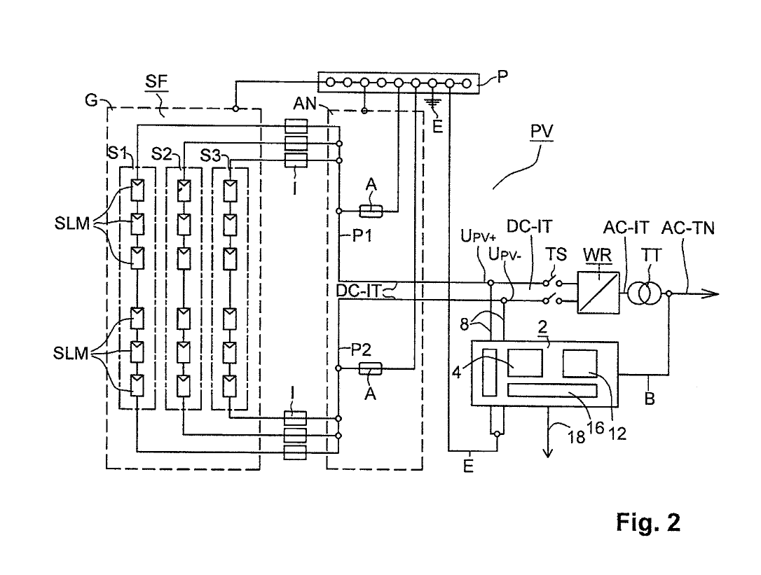

The device 2 according to the invention comprises a recording unit 4 coupled to a functional electrical connection line 6 of an electrical installation. The connection line 6 may be part of an existing current supply network (DC-IT in FIG. 2) or the feed line of an arbitrary electrical equipment to be monitored. On this electrical connection 6 the recording unit 4 records at least one already existing signal 8. The recorded signal 8 may for example be a variable required for normal operation of the electrical installation such as the operating voltage (UPV+, UPV− in FIG. 2) or a variable additionally imprinted on the line network such as a measuring current in the case of insulation monitoring. The recorded signal 8 or a variable derived therefrom is forwarded as the actual value 10 to a detection unit 12. In the detection unit 12 the measured actual value 10 is compared with a stored temporal reference pattern in order to recognize whether the deviation is tolerable or inadmissible and must therefore be regarded as in need of reporting.

In conjunction with the insulation monitoring function the reference data may be absolute values of the insulation resistance and/or threshold values for a maximum admissible rate of change of the insulation resistance value.

If the deviation exceeds a previously set limit or threshold value the detection unit 12 generates an alarm signal 14. This alarm signal may be emitted in optical or acoustic form and broadcast by means of a transmission unit 16. For example the alarm signal 14 may be sent to a central monitoring station via radio or cable in the form of a binary data packet 18 via a transmission unit 16 executed as a digital data interface.

In order to prevent the device 2 from being tampered with, this comprises a unit 20 for permanent self-monitoring.

FIG. 2 shows a block diagram of a photovoltaic installation with a device 2 according to the invention. In this constellation the function of recognising mechanical impacts is based on the recording of signals for determining an actual value of the insulation resistance.

The photovoltaic installation PV shown as an example comprises a field SF of solar current modules SLM. With the aid of this electrical equipment the direct voltages UPV+, UPV− are generated at a positive or negative pole P1, P2 of an insulated ungrounded direct voltage network DC-IT. The direct voltage network DC-IT thus represents the functional electrical connection (6 in FIG. 1), wherein the direct voltages UPV+ and UPV− existing on this connection line result in the signals 8 for recognising mechanical impacts.

The solar current modules SLM in the example of FIG. 2 are divided among three trains S1, S2, S3 each with six series-connected solar current modules SLM. The trains are connected in parallel via fuses I on the positive and negative poles P1, P2 of the direct current network DC-IT.

The photovoltaic direct voltages UPV+ and UPV− generated when the solar current modules are sufficiently irradiated, are supplied to an inverter WR via an isolating contactor TS. The inverter generates an isolated ungrounded alternating voltage network AC-IT on the output side, which ultimately feeds the energy via an intermediate isolating transformer TT into the alternating voltage network AC-TN with a grounded star point.

The field SF of solar current modules SLM is accommodated in a housing G which is connected via a main potential equalising bar P with the ground reference potential E. The electrical contacts of trains S1, S2, S3 leading out of housing G are directly connected via an additional junction box AN with poles P1, P2 of the direct voltage network DC-IT on the one hand, and via overvoltage conductors A with the main potential equalising bar P on the other.

The device 2 implemented according to the invention is connected to this typical photovoltaic installation PV. The device 2 is supplied with energy from the alternating voltage network AC-TN fed from the photovoltaic installation PV via a voltage supply B. Alternatively, in the case of stand-alone installations, the voltage supply B would be realised via a stand-alone energy source. As shown in detail in FIG. 1, the device 2 according to the invention includes a recording unit 4 for the actual value of the insulation resistance in the direct voltage network DC-IT. To this end the actual values of the photovoltaic direct voltages UPV+ and UPV− occurring on the poles P1 and P2 are cyclically recorded as signals and evaluated in the detection unit 12. An alarm signal is broadcast as data packet 18 via the transmission unit 16 to a central monitoring station via radio or a wired line.

1. A method for recognizing mechanical impacts on electrical installations which comprise a functional electrical connection with a power supply network or a storage medium, said method comprising:
recording at least one signal on the functional electrical connection to recognize a mechanical impact.

2. The method according to claim 1, in which recognition of the mechanic impact is effected by comparing an actual value of the recorded signal or an actual value of variables derived therefrom with a required value.

3. The method according to claim 1, in which a sharp change in the actual value is utilised as a recognition criterion for a mechanical impact.

4. The method according to claims 1, in which a rate of change in the actual value is utilised as a recognition criterion for a mechanical impact.

5. The method according to claim 1, in which an alarm signal is generated upon recognition of a mechanical impact.

6. The method according to claim 5, in which the alarm signal is transmitted remotely.

7. The method according to claim 1, including continuously monitoring said at least one signal for recognizing mechanical impacts.

8. The method according to claim 1, including monitoring a ground connection (E) of a device carrying out the method is monitored.

9. The method according to claim 1, in which recording the at least one signal is a cyclical operation.

10. The method according to claim 1, in which recording the at least one signal is a temporary activation.

11. A device for recognizing mechanical impacts on electrical installations said device comprises:
a functional electrical connection with at least one of a power supply network and a storage medium; and
a recording unit coupled with the functional electrical connection and recording at least one signal on the functional electrical connection.

12. The device according to claim 1, including a detection unit comparing an actual value of the recorded signal or an actual value of variables derived therefrom with a required value, wherein upon recognition of a mechanical impact in view of the value comparison generates an alarm signal.

13. The device according to claim 11, including a transmission unit transmitting the alarm signal remotely.

14. The device according to claim 11, including a unit for continuous self-monitoring for said at least one signal.

15. The device according to claim 11, in which the recording unit records signals indicative of an actual value of an insulation resistance.

16. The device according to claim 11, in which the recording unit records signals indicative of an electrical arc.

17. A photovoltaic installation (PV) with at least one solar current module (SLM) and with a device according to claim 11.
